(19) United States
(12) Patent Application Publication
(10) Pub. No.: US 2025/0125290 A1
(43) Pub. Date: Apr. 17, 2025

(54) DEVICE FOR SEMICONDUCTOR PACKAGE COMPRISING CONNECTING STRUCURE AND METHOD FOR MANUFACTURING THE SAME

(71) Applicant: SAMSUNG ELECTRONICS CO., LTD., SUWON-SI (KR)

(72) Inventors: HYUNSU HWANG, Suwon-si (KR); JUMYONG PARK, Suwon-si (KR); DONGJOON OH, Suwon-si (KR); SANGHOO CHO, Suwon-si (KR); JEONGGI JIN, Suwon-si (KR)

(21) Appl. No.: 18/647,497

(22) Filed: Apr. 26, 2024

(30) Foreign Application Priority Data
Oct. 12, 2023 (KR) 10-2023-0136144

(51) Int. Cl. H01L 23/00; H01L 21/48; H01L 23/498; H01L 23/522; H01L 23/532

(52) U.S. Cl. CPC H01L 24/05; H01L 21/4857; H01L 23/49822; H01L 23/5226; H01L 23/5329; H01L 24/03; H01L 2224/03464; H01L 2224/03614; H01L 2224/05082; H01L 2224/05573

(57) ABSTRACT

A semiconductor device includes a structure including a dielectric layer and a wire pattern embedded in the dielectric layer. The dielectric layer includes first regions and a second region around the first regions. The second region has an upper surface positioned at a lower level than upper surfaces of the first regions. A barrier layer is on the structure. The barrier layer is disposed on each first region among the first regions and is connected to the wire pattern. A seed metal layer is on the barrier layer. A conductive pad is on the seed metal layer.

### CROSS-REFERENCE TO RELATED APPLICATION

This application claims priority under 35 U.S.C. § 119 to Korean Patent Application No. 10-2023-0136144, filed on Oct. 12, 2023 in the Korean Intellectual Property Office, the disclosure of which is incorporated by reference in its entirety herein.

### 1. TECHNICAL FIELD

The present disclosure relates to a semiconductor device including a connecting structure included in a semiconductor package and a manufacturing method thereof.

### 2. DISCUSSION OF RELATED ART

As the size of electronic products are increasingly reduced, a flip chip bonding technology has been developed as a semiconductor package technology for connecting the semiconductor chips to the electronic products that they are applied to. The semiconductor chips and the electronic devices include conductive pads as a connecting structure to perform such flip chip bonding. The conductive pads are formed by forming a barrier layer and a seed metal layer, performing electrolytic plating, and then performing a wet etching process to remove the exposed barrier layer and seed metal layer from the conductive pad. Since a wet etching has an isotropic etching characteristic, undercuts are formed in the seed metal layer and the barrier layer during the process of forming the conductive pads.

The undercuts formed in the seed metal layer and barrier layer by the wet etching process may anchor a ring frame tape used in the subsequent device assembly process. As a result, if the ring frame tape remains in the connecting structure of the semiconductor device, it will have a negative impact on a product yield and a reliability.

### SUMMARY

According to an embodiment of the present disclosure, a semiconductor device includes a structure including a dielectric layer and a wire pattern embedded in the dielectric layer. The dielectric layer includes first regions and a second region around the first regions. The second region has an upper surface positioned at a lower level than upper surfaces of the first regions. A barrier layer is on the structure. The barrier layer is disposed on each first region among the first regions and is connected to the wire pattern. A seed metal layer is on the barrier layer. A conductive pad is on the seed metal layer.

According to an embodiment of the present disclosure, a semiconductor device includes a structure including a dielectric layer and a wire pattern embedded in the dielectric layer. The dielectric layer includes first regions and a second region around the first regions. The second region has an upper surface positioned at a lower level than upper surfaces of the first regions. A barrier layer is on the structure. The barrier layer is disposed on each first region among the first regions and is connected to the wire pattern. A seed metal layer is on the barrier layer. The seed metal layer has a side surface that is undercut in an inner direction with respect to a side surface of the barrier layer. A conductive pad is on the seed metal layer.

According to an embodiment of the present disclosure, a method of manufacturing a semiconductor device includes forming a dielectric layer on a substrate. The dielectric layer includes a wire pattern embedded therein. A barrier layer is formed on the dielectric layer. The barrier layer is connected to the wire pattern. A seed metal layer is formed on the barrier layer. A photoresist pattern is formed on the seed metal layer. Conductive pads are formed within the photoresist pattern. The photoresist pattern is removed to expose the seed metal layer. The exposed seed metal layer is removed by performing a wet etching process. Regions of the dielectric layer positioned below the conductive pad are first regions, and the region of the dielectric layer around the first regions is a second region. A dry etching process is performed to remove the barrier layer on the second region and to remove a portion of the surface of the dielectric layer of the second region. The second region has an upper surface positioned at a lower level than upper surfaces of the first regions.

In the process of forming the conductive pads, wet etching may be performed to remove the exposed seed metal layer, and the dry etching may be performed to remove a portion of the surface of the barrier layer and the dielectric layer. As a result, the upper surface of the dielectric layer in the first region where the barrier layer, the seed metal layer, and the conductive pad are disposed may have a higher level than the upper surface of the second region around the first region, and the seed metal layer may include the side undercut in the inward direction with reference to the side of the barrier layer.

For example, the seed metal layer on which the undercut is formed is disposed on the barrier layer on the first region of the dielectric layer, which has a higher level than the second region of the dielectric layer. According to the structure of this connecting structure and the manufacturing method of the connecting structure, the height of the seed metal layer where the undercut is formed is higher than the second region of the dielectric layer to which a ring frame tape is attached. Accordingly, the ring frame tape does not directly contact the undercut formed on the seed metal layer. Therefore, in the subsequent device assembly process using the ring frame tape, an anchoring of the ring frame tape may be prevented.

### BRIEF DESCRIPTION OF THE DRAWINGS

FIG. 1 is a cross-sectional view showing a semiconductor device including a connecting structure according to an embodiment of the present disclosure.

FIG. 2 is an enlarged cross-sectional view of a connecting structure in FIG. 1 according to an embodiment of the present disclosure.

FIG. 3 is a top plan view showing a seed metal layer of a connecting structure according to an embodiment of the present disclosure.

FIG. 4 is a top plan view showing a seed metal layer of a connecting structure according to an embodiment of the present disclosure.

FIG. 5 is a top plan view showing a seed metal layer of a connecting structure according to an embodiment of the present disclosure.

FIG. 6 is a cross-sectional view showing a semiconductor device including a connecting structure according to an embodiment of the present disclosure.

FIG. 7 is an enlarged cross-sectional view of a connecting structure in FIG. 6 according to an embodiment of the present disclosure.

FIG. 8 is a cross-sectional view showing a semiconductor device including a connecting structure according to an embodiment of the present disclosure.

FIG. 9 is a cross-sectional view showing a semiconductor device including a connecting structure according to an embodiment of the present disclosure.

FIG. 10 to FIG. 18 are a cross-sectional views showing a method for manufacturing a connecting structure according to embodiments of the present disclosure.

### DETAILED DESCRIPTION OF EMBODIMENTS

Hereinafter, examples of embodiments of the present disclosure will be described in detail with reference to the attached drawings. However, embodiments of the present disclosure may be modified in various ways and is not limited to the examples described herein.

In the drawings, elements irrelevant to the description of the present disclosure may be omitted for simplicity of explanation, and like reference numerals designate like elements throughout the specification.

Further, a size and a thickness of each composition illustrated in the drawing may be arbitrarily illustrated for the convenience of description so that the embodiments are not necessarily limited those illustrated in the drawing.

In the preset specification, when it is described that one component or layer is “connected” or “coupled” to another component or layer, it means that one component may be formed on the other component directly or with one or more other components or layers interposed therebetween. When it is described that one component or layer is “directly connected” or “directly coupled” to the other component or layer, it means that no intervening components or layers are interposed therebetween. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side.

Hereinafter, a semiconductor device including a connecting structure for a semiconductor package of an embodiment will be described with reference to the drawing.

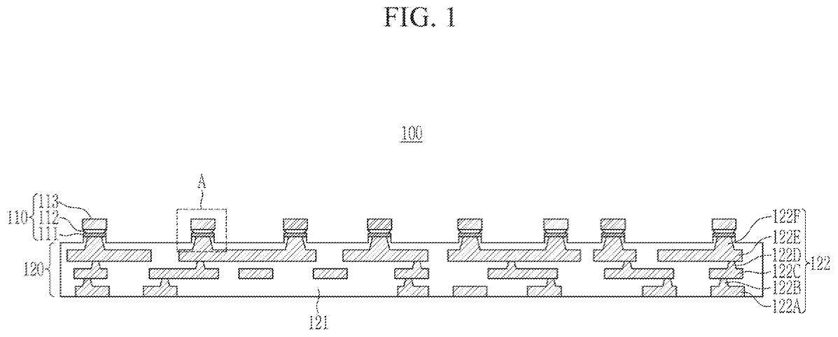

FIG. 1 is a cross-sectional view showing a semiconductor device 100 including a connecting structure 110 of an embodiment.

Referring to FIG. 1, the semiconductor device 100 includes a connecting structure 110 and a structure that comprises a redistribution layer (RDL) structure 120. In an embodiment, the semiconductor device 100 may include a redistribution layer substrate included in a semiconductor package, an interposer including a redistribution layer structure, or a semiconductor chip including a redistribution layer structure.

In an embodiment, the connecting structure 110 include a barrier layer 111, a seed metal layer 112, and a conductive pad 113. In an embodiment, the connecting structure 110 is physically connected to solder bumps of an external device through an assembly process. The connecting structure 110 electrically connects the redistribution layer structure 120 to an external device.

The barrier layer 111 is disposed on (e.g., disposed directly thereon) the dielectric layer 121 and the third redistribution layer via 122F. The barrier layer 111 is disposed between the third redistribution layer via 122F and the seed metal layer 112 (e.g., in a vertical direction), and electrically connects the seed metal layer 112 to the third redistribution layer via 122F. The barrier layer 111 suppresses the metal of the seed metal layer 112 and the metal of the conductive pad 113 from migrating to the dielectric layer 121. The suppression of the migration of the metal of the seed metal layer 112 and the metal of the conductive pad 113 can prevent the wire pattern 122 from short-circuiting. Additionally, the barrier layer 111 prevents oxidation chemical reactions that may occur between the dielectric layer 121 and the seed metal layer 112, and between the dielectric layer 121 and the conductive pad 113. As a result, a chemical stability between structures may be increased.

The seed metal layer 112 is disposed on (e.g., disposed directly thereon) the barrier layer 111. In an embodiment, the seed metal layer 112 extends conformally on the barrier layer 111. The seed metal layer 112 is disposed between the barrier layer 111 and the conductive pad 113 (e.g., in a vertical direction), and electrically connects the conductive pad 113 to the barrier layer 111.

In an embodiment, the redistribution layer structure 120 includes a dielectric layer 121 and a wire pattern 122 embedded within the dielectric layer 121. The dielectric layer 121 protects and insulates the wire pattern 122. A connecting structure 110 is disposed on (e.g., disposed directly thereon) the upper surface of the dielectric layer 121. An external device is disposed on the bottom surface of dielectric layer 121. In an embodiment, the dielectric layer 121 may include a photoimageable dielectric (PID) used in the redistribution process. The photoimageable dielectric is a material that may form a fine pattern by applying a photolithography process. In an embodiment, the photoimageable dielectric (PID) may include polyimide-based photoactive polymer, novolac-based photoactive polymer, polybenzoxazole, silicon-based polymer, acrylate-based polymer, or epoxy-based polymer. In an embodiment, the dielectric layer 121 is formed of an inorganic dielectric material such as silicon nitride, silicon oxide, etc. In an embodiment, the dielectric layer 121 may be formed by a CVD, ALD, or PECVD processes.

In an embodiment, the wire pattern 122 includes first redistribution layer lines 122A, first redistribution layer vias 122B, second redistribution layer lines 122C, second redistribution layer vias 122D, third redistribution layer lines 122E, and third redistribution layer vias 122F. However, embodiments of the present disclosure are not necessarily limited thereto. For example, in an embodiment, the redistribution layer structure 120 may include fewer or more redistribution layer lines and redistribution layer vias.

The first redistribution layer lines 122A are disposed between the external device and the first redistribution layer vias 122B (e.g., in the vertical direction). The first redistribution layer line 122A electrically connects the first redistribution layer via 122B to an external device. The first redistribution layer vias 122B are disposed between the first redistribution layer lines 122A and the second redistribution layer lines 122C (e.g., in the vertical direction). The first redistribution layer via 122B electrically connects the second redistribution layer line 122C to the first redistribution layer line 122A. The second redistribution layer lines 122C are disposed between the first redistribution layer vias 122B and the second redistribution layer vias 122D (e.g., in the vertical direction). The second redistribution layer line 122C electrically connects the second redistribution layer via 122D to the first redistribution layer via 122B. The second redistribution layer vias 122D are disposed between the second redistribution layer lines 122C and the third redistribution layer lines 122E (e.g., in the vertical direction). The second redistribution layer via 122D electrically connects the third redistribution layer line 122E to the second redistribution layer line 122C. The third redistribution layer lines 122E are disposed between the second redistribution layer vias 122D and the third redistribution layer vias 122F. The third redistribution layer line 122E electrically connects the third redistribution layer via 122F to the second redistribution layer via 122D. Third redistribution layer vias 122F are disposed between the barrier layer 111 and the third redistribution layer lines 122E (e.g., in the vertical direction). The third redistribution layer via 122F electrically connects the barrier layer 111 to the third redistribution layer line 122E.

In an embodiment, the first redistribution layer lines 122A, the first redistribution layer vias 122B, the second redistribution layer lines 122C, the second redistribution layer vias 122D, the third redistribution layer lines 122E, and the third redistribution layer vias 122F may each include at least one of copper, aluminum, tungsten, nickel, gold, tin, titanium, and alloys thereof. In an embodiment, the first redistribution layer lines 122A, the first redistribution layer vias 122B, the second redistribution layer lines 122C, the second redistribution layer vias 122D, the third redistribution layer lines 122E, and the third redistribution layer vias 122F may be formed by performing a sputtering process, respectively. In an embodiment, the first redistribution layer lines 122A, the first redistribution layer vias 122B, the second redistribution layer lines 122C, the second redistribution layer vias 122D, the third redistribution layer lines 122E, and the third redistribution layer vias 122F may be formed by performing an electrolytic plating after forming a seed metal layer, respectively.

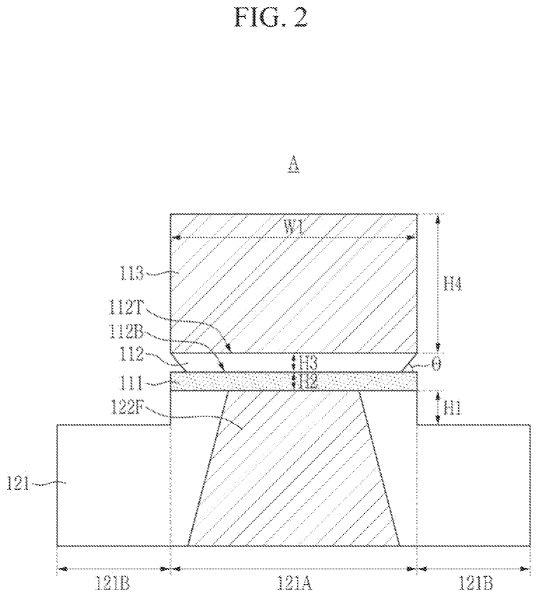

FIG. 2 is an enlarged cross-sectional view of a connecting structure 110 of a region A of a semiconductor device 100 of FIG. 1.

Referring to FIG. 2, the regions of the dielectric layer 121 that overlap the footprint of the connecting structure 110 is defined as first regions 121A. The region of the dielectric layer 121 other than the first regions 121A is defined as a second region 121B. In an embodiment, the third redistribution layer via 122F is positioned within the dielectric layer 121 of the first region 121A. In an embodiment, the third redistribution layer via 122F is not positioned within the dielectric layer 121 of the second region 121B. In an embodiment, the upper surface of the dielectric layer 121 of the first region 121A and the upper surface of the third redistribution layer via 122F have the same level as each other (e.g., are coplanar in a vertical direction). In an embodiment, a difference H1 of the level of the upper surface of the dielectric layer 121 of the first region 121A and the level of the upper surface of the dielectric layer 121 of the second region 121B may be in a range of about 750 Å to about 9,000 Å. In an embodiment, the dielectric layer 121 of the first region 121A may have a width in a range of about 1 μm to about 50 μm in the horizontal direction.

The barrier layer 111 is disposed on (e.g., disposed directly thereon) the first region 121A of the dielectric layer 121. In an embodiment, the barrier layer 111 may not be disposed on the second region 121B of the dielectric layer 121. In an embodiment, the barrier layer 111 is conformally disposed along the upper surface of the dielectric layer 121 and the upper surface of the third redistribution layer via 122F. The upper surface of the barrier layer 111 has a first portion that is in direct contact with the seed metal layer 112 and a second portion that does not contact the seed metal layer 112. In an embodiment, the barrier layer 111 may have a thickness H2 in a range of about 500 Å to about 3,000 Å in the vertical direction. In an embodiment, the barrier layer 111 may have a width in a range of about 1 μm to about 50 μm in the horizontal direction.

In an embodiment, the seed metal layer 112 is disposed on the first region 121A of the dielectric layer 121. In an embodiment, the seed metal layer 112 may not be disposed on the second region 121B of the dielectric layer 121. The seed metal layer 112 is conformally disposed along the barrier layer 111. In an embodiment, the seed metal layer 112 may have a thickness H3 in a range of about 500 Å to about 3,000 Å in the vertical direction. The seed metal layer 112 has a side surface (e.g., lateral side surfaces) undercut in the inner direction with respect to the side (e.g., lateral sides) of the barrier layer 111. For example, in an embodiment the width of the seed metal layer 112 in the horizontal direction decreases from the second surface 112T to the first surface 112B. In an embodiment, the angle θ between the second portion of the upper surface of the barrier layer 111 that does not contact the seed metal layer 112 and the side surface of the seed metal layer 112 may be in a range of about 30° to about 70°.

The conductive pad 113 is disposed on the first region 121A of the dielectric layer 121. In an embodiment, the conductive pad 113 may not be disposed on the second region 121B of the dielectric layer 121. The conductive pad 113 is conformally disposed along the seed metal layer 112, such as the second surface 112T of the seed metal layer 112. In an embodiment, the conductive pad 113 may have a thickness H4 in a range of about 1 μm to about 20 μm in the vertical direction. In an embodiment, the width W1 of the conductive pad 113 may be in a range of about 1 μm to about 50 μm in the horizontal direction.

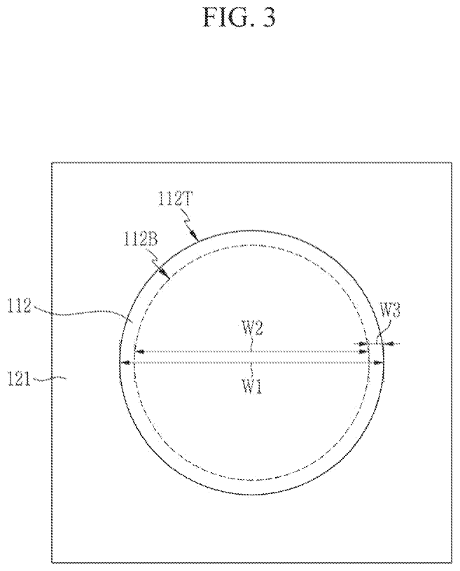

FIG. 3 is a top plan view showing a seed metal layer 112 of a connecting structure 110 of an embodiment.

Referring to FIG. 3, the bottom surface of the seed metal layer 112 in direct contact with the barrier layer 111 is defined as a first surface 112B, and the upper surface of the seed metal layer 112 in direct contact with the conductive pad 113 is defined as a second surface 112T. The outline of the first surface 112B of the seed metal layer 112 of the connecting structure 110 is shown as a dotted line, and the outline of the second surface 112T of the seed metal layer 112 is shown as a solid line. In an embodiment, the first surface 112B of the seed metal layer 112 may have a circular shape. In an embodiment, the second surface 112T of the seed metal layer 112 may have a circular shape. In an embodiment, the barrier layer 111 disposed below (e.g., directly below) the seed metal layer 112 and the conductive pad 113 disposed above (e.g., directly above) the seed metal layer 112 may have a circular shape. In an embodiment, the width (e.g., a diameter W2) of the first surface 112B of the seed metal layer 112 may be in a range of about 0.9 μm to about 47 μm. In an embodiment, the width (e.g., a diameter W1) of the second surface 112T of the seed metal layer 112 may be in a range of about 1 μm to about 50 μm. In an embodiment, corresponding to ½ of the difference between the width (e.g., the diameter W1) of the second surface 112T of the seed metal layer 112 and the width (e.g., the diameter W2) of the first surface 112B of the seed metal layer 112, the width W3 of the second portion of the upper surface of the barrier layer 111 that does not directly contact the seed metal layer 112 may be in a range of about 0.05 μm to about 1.5 μm.

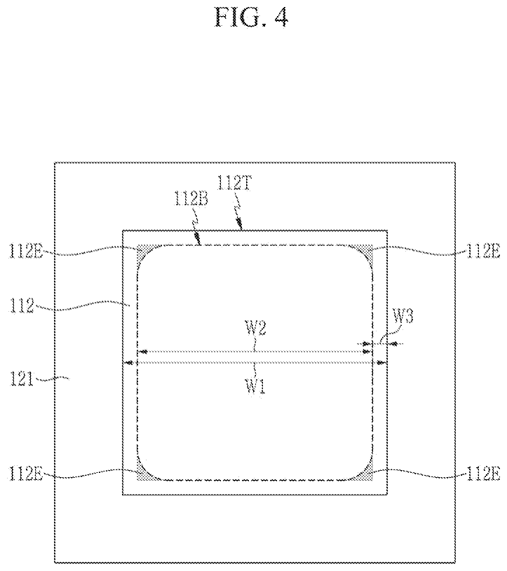

FIG. 4 is a top plan view showing a seed metal layer 112 of a connecting structure 110 of an embodiment.

Referring to FIG. 4, the bottom surface of the seed metal layer 112 in direct contact with the barrier layer 111 is defined as a first surface 112B, and the upper surface of the seed metal layer 112 in direct contact with the conductive pad 113 is defined as a second surface 112T. The outline of the first surface 112B of the seed metal layer 112 of the connecting structure 110 is shown as a dotted line, and the outline of the second surface 112T of the seed metal layer 112 is shown as a solid line. In an embodiment, the first surface 112B of the seed metal layer 112 may have a quadrangle shape with curved corners. In an embodiment, in the process of etching the seed metal layer 112 as a target, when the undercutting occurs on the side of the seed metal layer 112, an over-etching occurs at the corner portion 112E of the seed metal layer 112 so that the first surface 112B of the seed metal layer 112 may have the shape of a quadrangle with curved corners. In an embodiment, the second surface 112T of the seed metal layer 112 may have a quadrangle shape. In an embodiment, the barrier layer 111 disposed below the seed metal layer 112 and the conductive pad 113 disposed above the seed metal layer 112 may have a quadrangle shape. In an embodiment, the width W2 of the first surface 112B of the seed metal layer 112 may be in a range of about 0.9 μm to about 47 μm. In an embodiment, the width W1 of the second surface 112T of the seed metal layer 112 may be in a range of about 1 μm to about 50 μm. In an embodiment, corresponding to ½ of the difference between the width W1 of the second surface 112T of the seed metal layer 112 and the width W2 of the first surface 112B of the seed metal layer 112, the width W3 of the second portion of the upper surface of the barrier layer 111 that does not contact the seed metal layer 112 may be in a range of about 0.05 μm to about 1.5 μm.

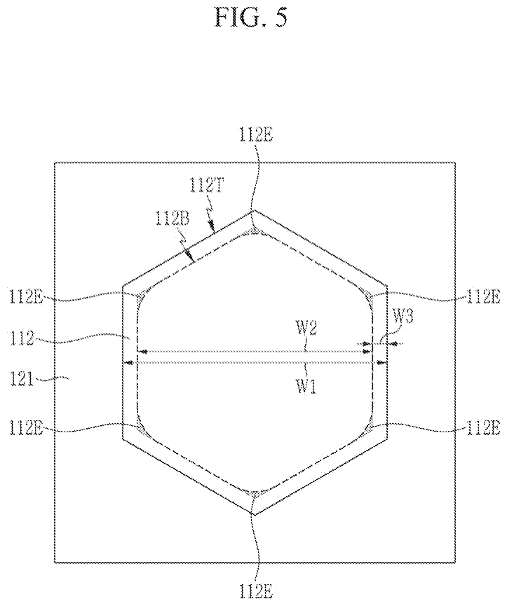

FIG. 5 is a top plan view showing a seed metal layer 112 of a connecting structure 110 according to an embodiment.

Referring to FIG. 5, the bottom surface of the seed metal layer 112 in direct contact with the barrier layer 111 is defined as a first surface 112B, and the upper surface of the seed metal layer 112 in direct contact with the conductive pad 113 is defined as a second surface 112T. The outline of the first surface 112B of the seed metal layer 112 of the connecting structure 110 is shown as a dotted line, and the outline of the second surface 112T of the seed metal layer 112 is shown as a solid line. In an embodiment, the first surface 112B of the seed metal layer 112 may have a hexagon shape with curved corners. In an embodiment, in the process of performing the etching of the seed metal layer 112 as a target, when the undercutting occurs on the side of the seed metal layer 112, the corner portion 112E of the seed metal layer 112 is over-etched, so that the first surface 112B of the seed metal layer 112 may have the shape of the hexagon with curved corners. In an embodiment, the second surface 112T of the seed metal layer 112 may have a hexagon shape. In an embodiment, the barrier layer 111 disposed below the seed metal layer 112 and the conductive pad 113 disposed above the seed metal layer 112 may have a hexagon shape. In an embodiment, the width W2 of the first surface 112B of the seed metal layer 112 may be in a range of about 0.9 μm to about 47 μm. In an embodiment, the width W1 of the second surface 112T of the seed metal layer 112 may be in a range of about 1 μm to about 50 μm. In an embodiment, corresponding to ½ of the difference between the width (the diameter; W1) of the second surface 112T of the seed metal layer 112 and the width (the diameter; W2) of the first surface 112B of the seed metal layer 112, the width W3 of the second portion of the upper surface of the barrier layer 111 that does not contact the seed metal layer 112 may be in a range of about 0.05 μm to about 1.5 μm.

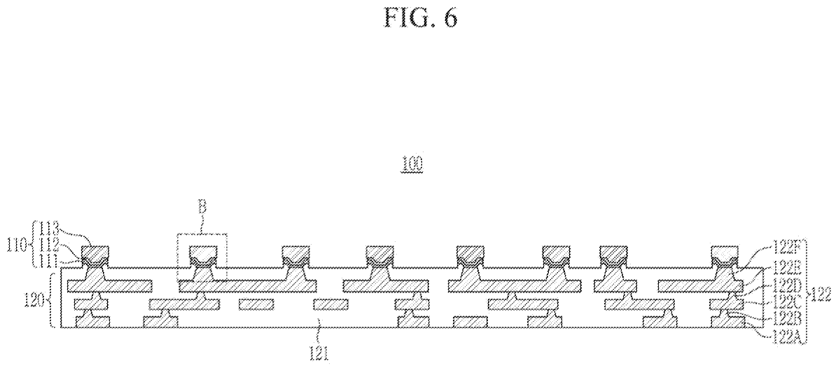

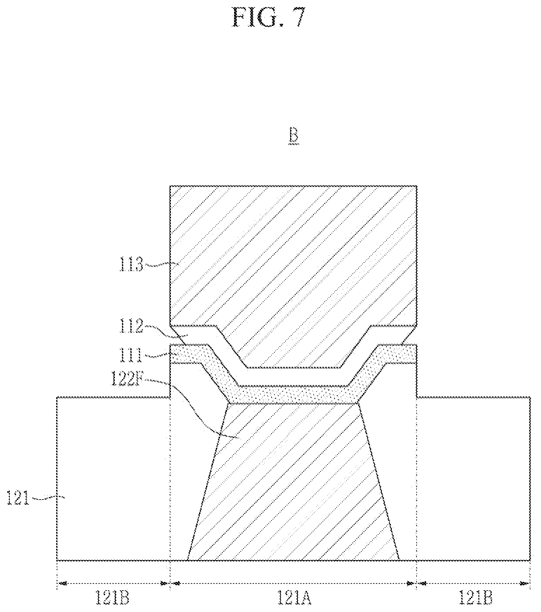

FIG. 6 is a cross-sectional view showing a semiconductor device 100 including a connecting structure 110 according to an embodiment. FIG. 7 is an enlarged cross-sectional view of a region of a connecting structure 110 of a region B of a semiconductor device 100 in FIG. 6.

Referring to FIG. 6 and FIG. 7, the semiconductor device 100 includes a connecting structure 110 and a redistribution layer (RDL) structure 120. The connecting structure 110 includes a barrier layer 111, a seed metal layer 112, and a conductive pad 113.

In the first region 121A, the dielectric layer 121 includes a through hole. In an embodiment, an upper surface of the third redistribution layer via 122F is exposed by the through hole. In an embodiment, the through hole may include a sloped inner surface. The barrier layer 111 extends conformally along the bottom surface (e.g., the upper surface of the third redistribution layer via 122F) and the inner surface of the through hole, and the upper surface of the dielectric layer 121 of the first region 121A. The seed metal layer 112 extends conformally along the barrier layer 111. The conductive pad 113 is disposed on (e.g., directly thereon) the seed metal layer 112.

In addition to the above, the description about the connecting structure 110 and the redistribution layer structure 120 may be applied with the contents of the connecting structure 110 and the redistribution layer structure 120 described in relation to embodiments shown in FIG. 1 to FIG. 5.

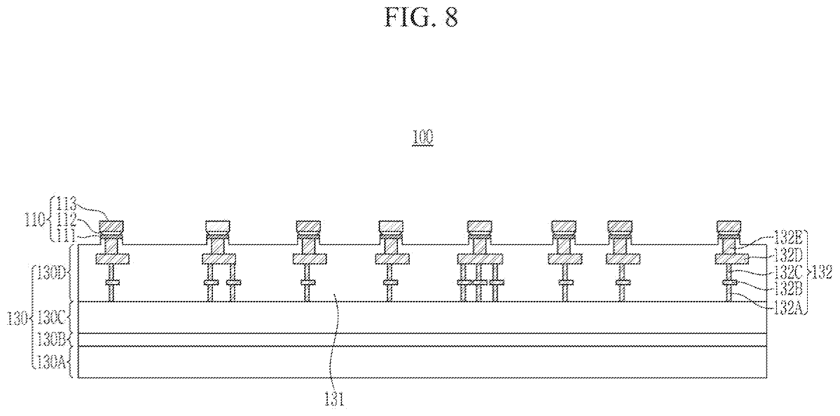

FIG. 8 is a cross-sectional view showing an embodiment of a semiconductor device 100 including a connecting structure 110.

Referring to FIG. 8, the semiconductor device 100 includes a connecting structure 110 and a semiconductor chip 130. In an embodiment, the connecting structures 110 may be used to connect the semiconductor chip 130 to an external device. The contents concerning the connecting structure 110 may be applied with the contents concerning the connecting structure 110 described in relation to embodiments shown in FIG. 1 to FIG. 7.

The semiconductor chip 130 include a substrate 130A, a front end of the line (FEOL) structure 130B including an integrated circuit, a middle end of the line (MEOL) structure 130C including a wire pattern, and a back end of the line (BEOL) structure 130D. In an embodiment, the FEOL structure 130B, MEOL structure 130C and BEOL structure 130D may be consecutively stacked in the vertical direction. In an embodiment, the semiconductor chip 130 may include a non-memory semiconductor. In an embodiment, the semiconductor chip 130 may be a system on chip, an application processor (AP), a central processing unit (CPU) or a graphic processing unit (GPU). In an embodiment, the semiconductor chip 130 may include a memory semiconductor. In an embodiment, the semiconductor chip 130 may be a static random access memory (SRAM), a dynamic random access memory (DRAM), a high bandwidth memory (HBM), or a flash memory. In FIG. 8, the illustration and the description of the components included in the substrate 130A, the FEOL structure 130B including the integrated circuit, and the MEOL structure 130C including the wire pattern are omitted for economy of description.

In an embodiment, the BEOL structure 130D of the semiconductor chip 130 includes a dielectric layer 131 and a wire pattern 132 in the dielectric layer 131.

The dielectric layer 131 is an interlayer insulating layer that protects and insulates the wire pattern 122. The connecting structure 110 is disposed on (e.g., disposed directly thereon) the upper surface of the dielectric layer 131. The MEOL structure 130C is disposed on (e.g., disposed directly thereon) the bottom surface of the dielectric layer 121. In an embodiment, the dielectric layer 131 may include SiO₂, SiOC, SiOH, SiOCH, or a low-k dielectric layer. For example, in an embodiment the low-k dielectric layer may be a material having a lower dielectric constant than silicon oxide.

In an embodiment, the wire pattern 132 includes a first contact plug 132A, a wire 132B, a second contact plug 132C, a metal pad 132D, and a third contact plug 132E. The first contact plug 132A is disposed between a lower wire and the wire 132B (e.g., in the vertical direction), and electrically connects the wire 132B to the lower wire. The wire 132B is disposed between the first contact plug 132A and the second contact plug 132C (e.g., in the vertical direction), and electrically connects the second contact plug 132C to the first contact plug 132A. The metal pad 132D is disposed between the second contact plug 132C and the third contact plug 132E (e.g., in the vertical direction), and electrically connects the third contact plug 132E to the second contact plug 132C. In an embodiment, the metal pad 132D is formed with a thicker thickness (e.g., length in the vertical direction) than the wire 132B. The third contact plug 132E is disposed between the metal pad 132D and the barrier layer 111 (e.g., in the vertical direction), and electrically connects the barrier layer 111 to the metal pad 132D. However, embodiments of the present disclosure are not necessarily limited thereto. In an embodiment, the third contact plug 132E may be omitted, and the barrier layer 111 may be directly connected to the metal pad 132D.

In an embodiment, the first contact plug 132A, the wire 132B, the second contact plug 132C, and the third contact plug 132E may include Al, Cu, Sn, Ni, Au, Pt, W or a combination thereof, respectively. In an embodiment, the metal pad 132D may include Al, Cu, Ni, Co, Ag, Pt, Ru, W, WN, Ti, TIN, Ta, TaN, or a combination thereof.

However, embodiments of the present disclosure are not necessarily limited thereto and the numbers of the contact plugs, wires and metal pads included in the BEOL structure 130D may vary from that shown in FIG. 8.

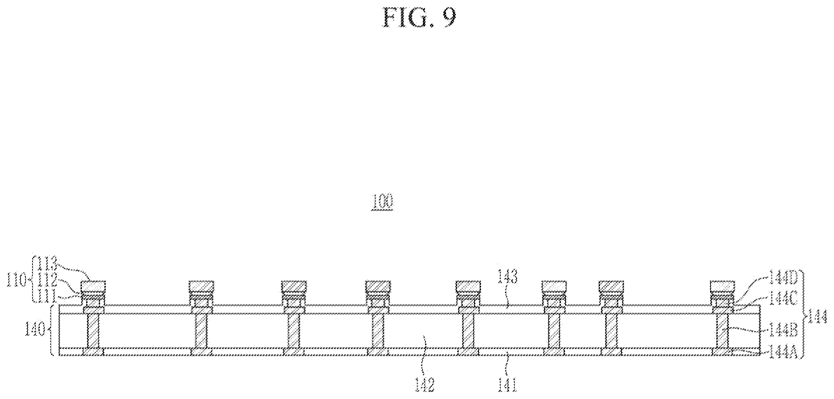

FIG. 9 is a cross-sectional view showing an embodiment of a semiconductor device 100 including a connecting structure 110.

Referring to FIG. 9, the semiconductor device 100 includes a connecting structure 110 and a structure comprising a silicon interposer 140. In an embodiment, the connecting structures 110 may be used to connect the silicon interposer 140 to an external device. The contents concerning the connecting structure 110 may be applied with the contents concerning the connecting structure 110 described in relation to embodiments shown in FIG. 1 to FIG. 7.

In an embodiment, the silicon interposer 140 includes a lower protection insulation layer 141, an interposer substrate 142, an upper protection insulation layer 143, and a wire pattern 144. The lower protection insulation layer 141 protects and insulates the lower connecting pad 144A. The interposer substrate 142 is disposed on (e.g., disposed directly thereon) the upper surface of the lower protection insulation layer 141. An external device is disposed on the bottom surface of the lower protection insulation layer 141. In an embodiment, the lower protection insulation layer 141 may include an organic material such as a photoimageable dielectric (PID). In an embodiment, the lower protection insulation layer 141 may include an inorganic material such as silicon, silicon nitride, or silicon oxide.

The interposer substrate 142 protects and insulates through silicon vias (TSV) 144B. An upper protection insulation layer 143 and upper connecting pads 144C are disposed on the upper surface of the interposer substrate 142. A lower protection insulation layer 141 and a lower connecting pads 144A are disposed on the bottom surface of the interposer substrate 142. In an embodiment, the interposer substrate 142 may be formed of a silicon wafer.

The upper protection insulation layer 143 protects and insulates an upper connecting pad 144C and a via 144D. A connecting structure 110 is disposed on (e.g., disposed directly thereon) the upper surface of the upper protection insulation layer 143. An interposer substrate 142 is disposed on (e.g., disposed directly thereon) the bottom surface of the upper protection insulation layer 143. In an embodiment, the upper protection insulation layer 143 may include an organic material such as a photoimageable dielectric (PID). In an embodiment, the upper protection insulation layer 143 may include an inorganic material such as silicon, silicon nitride, or silicon oxide.

In an embodiment, the wire pattern 132 includes lower connecting pads 144A, through silicon vias (TSV) 144B, upper connecting pads 144C, and vias 144D. The lower connecting pad 144A is disposed between a connecting member and the through silicon via (TSV) 144B (e.g., in the vertical direction), and electrically connects the through silicon via (TSV) 144B to the connecting member. The through silicon via (TSV) 144B is disposed between the lower connecting pad 144A and the upper connecting pad 144C (e.g., in the vertical direction), and electrically connects the upper connecting pad 144C to the lower connecting pad 144A. The upper connecting pad 144C is disposed between the through silicon via (TSV) 144B and the via 144D (e.g. in the vertical direction), and electrically connects the via 144D to the through silicon via (TSV) 144B. The via 144D is disposed between the upper connecting pad 144C and the barrier layer 111 (e.g., in the vertical direction), and electrically connects the barrier layer 111 to the upper connecting pad 144C. However, embodiments of the present disclosure are not necessarily limited thereto. For example, in an embodiment, the via 144D may be omitted, and the barrier layer 111 may be directly connected to the upper connecting pad 144C.

In an embodiment, the lower connecting pads 144A, the upper connecting pads 144C, and the vias 144D may each include at least one of copper, aluminum, silver, tin, gold, nickel, lead, titanium, and alloys thereof. In an embodiment, the through silicon via (TSV; 144B) may include at least one of tungsten, aluminum, copper, and alloys thereof.

However, embodiments of the present disclosure are not necessarily limited thereto and the numbers of the lower connecting pads, penetrating silicon vias, upper connecting pads, and vias included in the silicon interposer may vary.

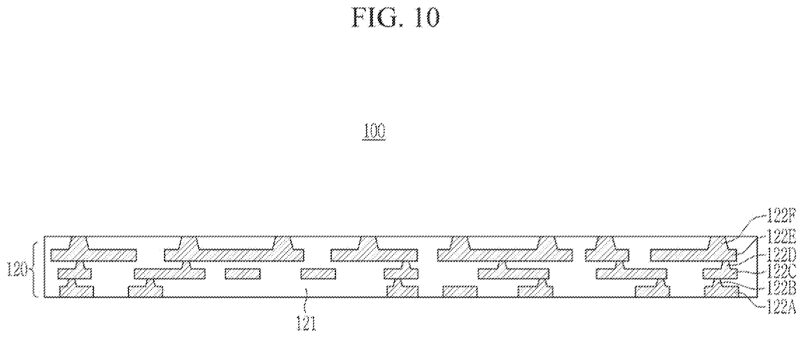

FIG. 10 to FIG. 18 are cross-sectional views showing a method of manufacturing a connecting structure 110 of FIG. 1. The manufacturing method of FIG. 10 to FIG. 18 is applied to the method of manufacturing the connecting structure 110 of FIG. 6, FIG. 8, and FIG. 9.

FIG. 10 is a cross-sectional view showing a step for providing a redistribution layer structure 120.

Referring to FIG. 10, the redistribution layer structure 120 may be provided. In an embodiment, the redistribution layer structure 120 may be a redistribution layer substrate, a redistribution layer interposer, or a redistribution layer structure within a semiconductor chip. The redistribution layer structure 120 may be formed on the substrate. In an embodiment, the substrate may include a wafer or a carrier.

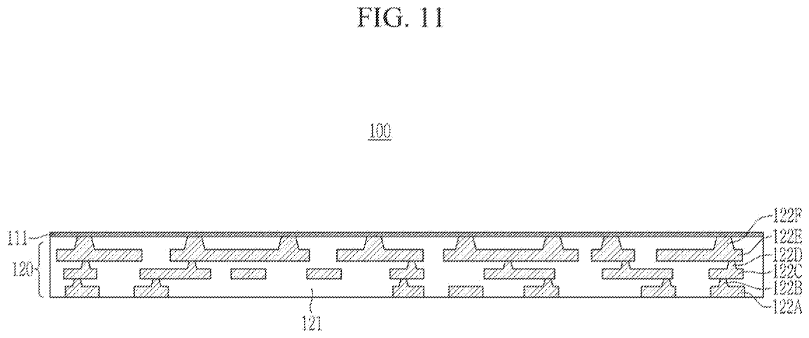

FIG. 11 is a cross-sectional view showing a step of forming a barrier layer 111 on the redistribution layer structure 120.

Referring to FIG. 11, a barrier layer 111 is formed on (e.g., formed directly thereon) the dielectric layer 121 and the third redistribution layer via 122F. In an embodiment, the barrier layer 111 may include at least one of titanium, titanium nitride, tantalum, and tantalum nitride. Titanium, titanium nitride, tantalum, and tantalum nitride are difficult to be diffused to the dielectric layer 121, so the seed metal layer 112 and the conductive pad 113 are prevented from being diffused into the dielectric layer 121. In an embodiment, the barrier layer 111 may be formed by performing a PVD process. In an embodiment, the barrier layer 111 may be formed by performing a sputtering process.

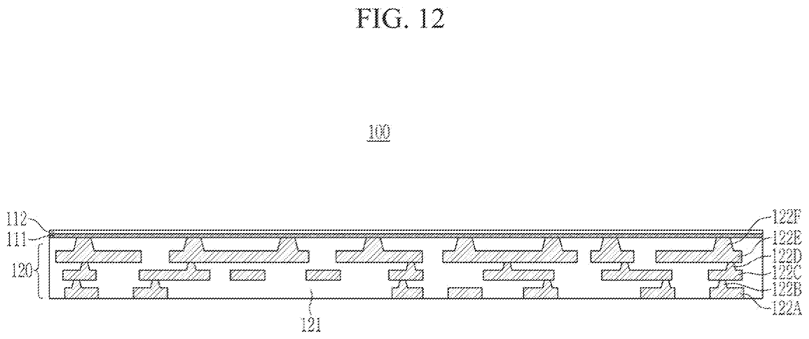

FIG. 12 is a cross-sectional view showing a step of forming a seed metal layer 112 on the barrier layer 111.

Referring to FIG. 12, the seed metal layer 112 is formed on (e.g., formed directly thereon) the barrier layer 111. In an embodiment, the seed metal layer 112 may include copper. In an embodiment, the seed metal layer 112 is formed by an electroless plating process. In an embodiment, a cleaning process or a metal catalyst activation pretreatment process may be performed prior to the performing of the electroless plating process. In an embodiment, the seed metal layer 112 is formed by a sputtering process.

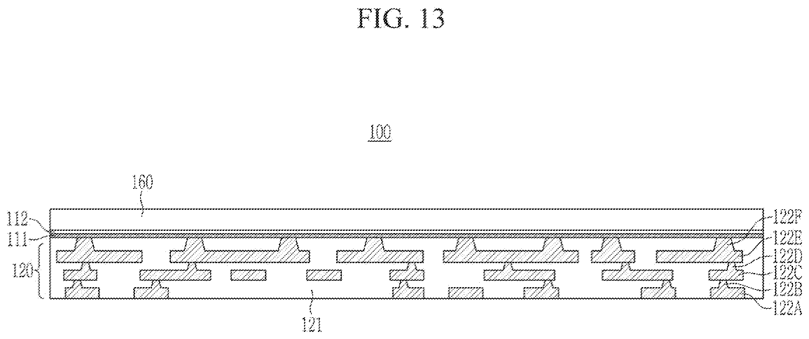

FIG. 13 is a cross-sectional view showing a step of forming a photoresist 160 on the seed metal layer 112.

Referring to FIG. 13, the photoresist 160 is formed on (e.g., formed directly thereon) the seed metal layer 112. In an embodiment, the photoresist 160 may be formed through a spin coating process. In an embodiment, the photoresist 160 may include an organic polymer resin including a photoactive material.

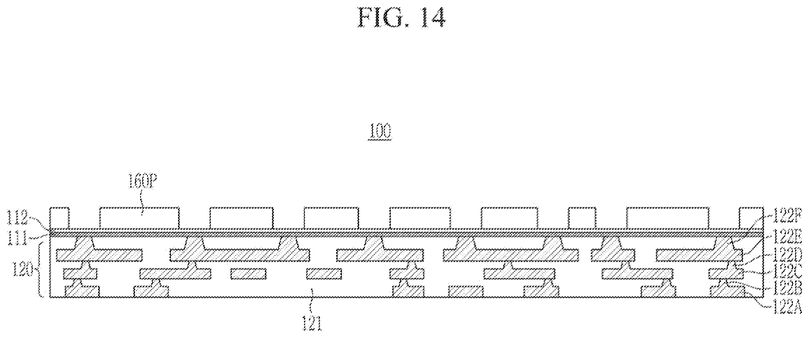

FIG. 14 is a cross-sectional view showing a step of forming a photoresist pattern 160P by exposing and developing the photoresist 160.

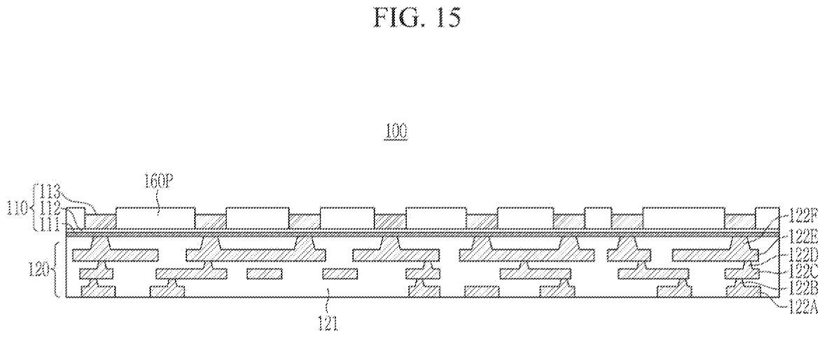

Referring to FIG. 14, the photoresist 160 may be exposed and developed to form a photoresist pattern 160P. The photoresist pattern 160P includes openings. In an embodiment, each of the openings has a circular, quadrangle, or hexagon shape (e.g., in a plan view). However, embodiments of the present disclosure are not necessarily limited thereto and the respective shape of the openings may further vary. FIG. 15 is a cross-sectional view showing a step of forming conductive pads 113 on the seed metal layer 112.

Referring to FIG. 15, the conductive pads 113 are formed on (e.g., formed directly thereon) the seed metal layer 112. In an embodiment, the conductive pads 113 may be formed by an electrolytic plating. For example, the conductive pads 113 are formed by growing a metal layer from the seed metal layer 112 formed first by the electrolytic plating. In an embodiment, an annealing process may be performed after the conductive pads 113 are formed. In an embodiment, the conductive pads 113 may include copper.

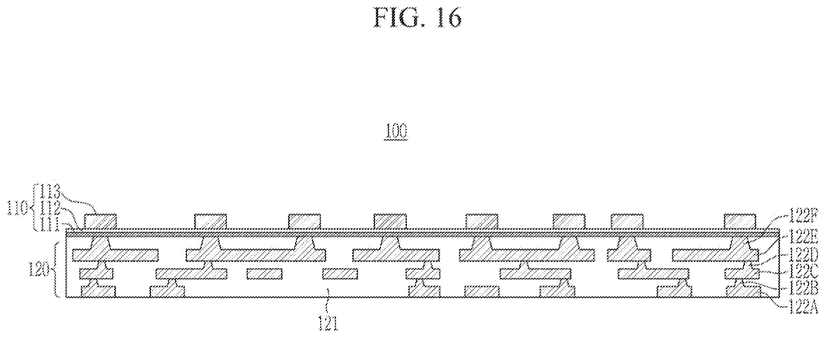

FIG. 16 is a cross-sectional view showing a step of removing the photoresist pattern 160P.

Referring to FIG. 16, the photoresist pattern 160P is removed between the conductive pads 113. In an embodiment, the photoresist pattern 160P may be removed by at least one of an etching, ashing, and stripping process.

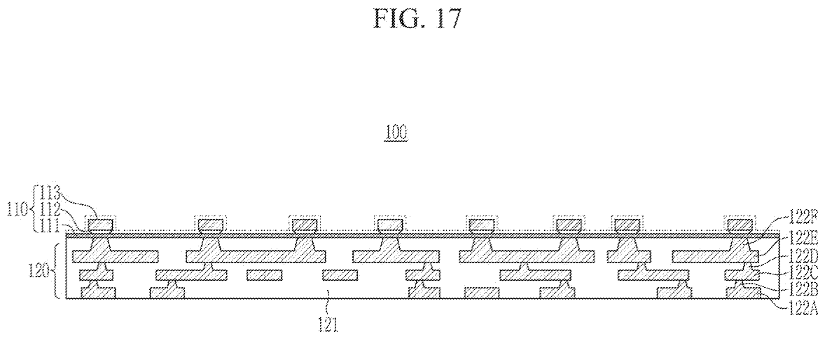

FIG. 17 is a cross-sectional view showing a step for performing a wet etching.

Referring to FIG. 17, a wet etching is performed to remove a portion of the surface of each conductive pad 113 and to remove the exposed portions of the seed metal layer 112. The regions of the dielectric layer 121 positioned below the conductive pads 113 that are not removed is defined as first regions 121A, and the region of the dielectric layer 121 around the first regions 121A is defined as a second region 121B. After performing the wet etching, the barrier layer 111 on the second region 121B is exposed, and the side of the seed metal layer 112 is undercut in the inner direction.

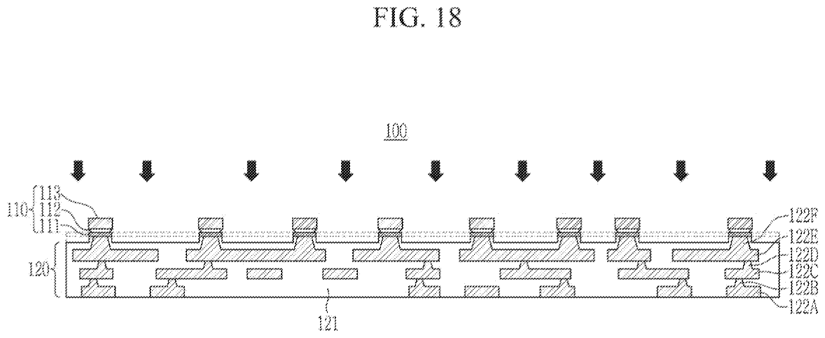

FIG. 18 is a cross-sectional view showing a step for performing a dry etching.

Referring to FIG. 18, by performing the dry etching, the barrier layer 111 is removed on the second region 121B, and a portion of the surface of the dielectric layer 121 of the second region 121B is removed. After performing the dry etching, the dielectric layer 121 of the second region 121B has the upper surface of a lower level than the upper surface of the dielectric layer 121 of the first regions 121A. Additionally, the side of the seed metal layer 112 has a shape undercut in the inner direction with reference to the side of the barrier layer 111. In an embodiment, the dry etching gas may include at least one of Cl₂, BCl₃, CHF₃, and O₂. In an embodiment, the etch selectivity of the dielectric layer 121 with respect to the barrier layer 111 may be in a range of about 30:1 to about 100:1.

While the present disclosure has been described in connection with example embodiments, it is to be understood that the present disclosure is not limited to the described embodiments.

What is claimed is:

1. A semiconductor device comprising:
a structure including a dielectric layer and a wire pattern embedded in the dielectric layer, wherein the dielectric layer includes first regions and a second region around the first regions, the second region has an upper surface positioned at a lower level than upper surfaces of the first regions;
a barrier layer on the structure, wherein the barrier layer is disposed on each first region among the first regions and is connected to the wire pattern;
a seed metal layer on the barrier layer; and
a conductive pad on the seed metal layer.

2. The semiconductor device of claim 1, wherein:
the structure includes a redistribution layer (RDL) structure.

3. The semiconductor device of claim 1, wherein:
the dielectric layer includes a photoimageable dielectric (PID).

4. The semiconductor device of claim 1, wherein:
the structure includes a silicon interposer or a semiconductor chip.

5. The semiconductor device of claim 1, wherein:
the dielectric layer includes SiO₂, SiOC, SiOH, SiOCH, or a low-k dielectric layer.

6. The semiconductor device of claim 1, wherein:
the upper surface of the dielectric layer of the first region is higher than the upper surface of the dielectric layer of the second region in a range of about 750 Å to about 9,000 Å.

7. The semiconductor device of claim 1, wherein:
the barrier layer has a thickness in a range of about 500 Å to about 3,000 Å in a vertical direction.

8. The semiconductor device of claim 1, wherein:
the seed metal layer has a thickness in a range of about 500 Å to about 3,000 Å in a vertical direction.

9. A semiconductor device comprising:
a structure including a dielectric layer and a wire pattern embedded in the dielectric layer, wherein the dielectric layer includes first regions and a second region around the first regions, the second region has an upper surface positioned at a lower level than upper surfaces of the first regions;
a barrier layer on the structure, wherein the barrier layer is disposed on each first region among the first regions and is connected to the wire pattern;
a seed metal layer on the barrier layer, wherein the seed metal layer has a side surface that is undercut in an inner direction with respect to a side surface of the barrier layer; and
a conductive pad on the seed metal layer.

10. The semiconductor device of claim 9, wherein:
the seed metal layer includes a first surface in direct contact with the barrier layer and a second surface in direct contact with the conductive pad; and
the seed metal layer has a width in a horizontal direction that decreases from the second surface to the first surface.

11. The semiconductor device of claim 10, wherein:
a width of the first surface is in a range of about 0.9 μm to about 47 μm.

12. The semiconductor device of claim 10, wherein:
a width of the second surface is in a range of about 1 μm to about 50 μm.

13. The semiconductor device of claim 9, wherein:
the barrier layer has an upper surface that includes a first portion in direct contact with the seed metal layer and a second portion that does not directly contact the seed metal layer.

14. The semiconductor device of claim 13, wherein:
an angle between the second portion of the barrier layer and the side surface of the seed metal layer is in a range of about 30° to about 70°.

15. The semiconductor device of claim 9, wherein:
the dielectric layer includes a through hole within each of the first regions, the wire pattern is exposed in the through hole; and
the barrier layer extends conformally along a bottom surface and an inner surface of the through hole, and the upper surface of the dielectric layer in each of the first regions.

16. The semiconductor device of claim 15, wherein:
the seed metal layer extends conformally along the barrier layer.

17. A method of manufacturing a semiconductor device comprising:
forming a dielectric layer on a substrate, the dielectric layer including a wire pattern embedded therein;
forming a barrier layer on the dielectric layer, wherein the barrier layer is connected to the wire pattern;
forming a seed metal layer on the barrier layer;
forming a photoresist pattern on the seed metal layer;
forming conductive pads within the photoresist pattern;
removing the photoresist pattern to expose the seed metal layer;
removing the exposed seed metal layer by performing a wet etching process, wherein regions of the dielectric layer positioned below the conductive pad are first regions, and the region of the dielectric layer around the first regions is a second region; and
performing a dry etching process to remove the barrier layer on the second region and to remove a portion of the surface of the dielectric layer of the second region, wherein the second region has an upper surface positioned at a lower level than upper surfaces of the first regions.

18. The method of manufacturing the semiconductor device of claim 17, wherein:
the photoresist pattern includes openings, each of the openings has a shape of a circle, quadrangle, or hexagon.

19. The method of manufacturing the semiconductor device of claim 17, wherein:
an etch selectivity of the dielectric layer for the barrier layer is in a range of about 30:1 to about 100:1.

20. The method of manufacturing the semiconductor device of claim 17, wherein in the forming of the seed metal layer on the barrier layer, the seed metal layer is formed by an electroless plating process.
